(19) United States
(12) Patent Application Publication
(10) Pub. No.: US 2025/0194117 A1
(43) Pub. Date: Jun. 12, 2025

(54) METHOD OF MANUFACTURING CAPACITOR ARRAY

(71) Applicant: NANYA TECHNOLOGY CORPORATION, New Taipei City (TW)

(72) Inventor: Zhi-Xuan SHEN, Taipei City (TW)

(21) Appl. No.: 18/536,343

(22) Filed: Dec. 12, 2023

(51) Int. Cl. H01L 21/311; H01L 21/3115

(52) U.S. Cl. CPC H10D 1/68; H01L 21/31116; H01L 21/31144; H01L 21/3115

(57) ABSTRACT

Embodiments of this disclosure provide a method of manufacturing a capacitor array, including the following steps. A substrate including a first cap layer over the substrate, a second cap layer on the first cap layer and a first hard mask layer on the second cap layer is provided. A photoresist layer is formed on the first hard mask in the peripheral area to expose the first hard mask in the array area. An impurity is doped in the exposed first hard mask layer to form a second hard mask layer. A pattern layer is formed on the first hard mask layer and the second hard mask layer to expose exposed portions on a surface of the second hard mask layer. Trenches are formed by etching. A capacitor is formed in each of the trenches.

### BACKGROUND

### Field of Invention

The present disclosure relates to a method of manufacturing a capacitor array. More particularly, the present disclosure relates to a method of manufacturing a capacitor array through doping an impurity.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. Due to shrinking the size of the semiconductor structure, in addition to increasing the difficulty of the manufacturing process, the components in the semiconductor structures are also prone to leakage resulting from too close distances.

As a result, in the semiconductor manufacturing process, how to reduce the leakage to improve the process yield of the semiconductor structure has become an important issue.

### SUMMARY

Embodiments of this disclosure provide a method of manufacturing a capacitor array, including the following steps. A substrate including a first cap layer over the substrate, a second cap layer on the first cap layer and a first hard mask layer on the second cap layer is provided. The substrate is defined with an array area and a peripheral area. A photoresist layer is formed on the first hard mask in the peripheral area and the first hard mask in the array area is exposed. A P-type impurity is doped in the first hard mask layer exposed by the photoresist layer to form a second hard mask layer. A pattern layer is formed on the first hard mask layer and the second hard mask layer to expose a plurality of exposing portions on a surface of the second hard mask layer. The second hard mask layer, the second cap layer and the first cap layer at the plurality of exposing portions are etched to form a plurality of trenches. A capacitor is formed in each of the plurality of trenches.

In some embodiments, a concentration of the P-type impurity is a range from 2×10¹⁴ to 2×10¹⁸ ions/cm².

In some embodiments, the P-type impurity is boron.

In some embodiments, forming the plurality of trenches is performed by a dry etching process with halogen-based gas.

In some embodiments, the first cad layer has a first thickness, the second cad layer has a second thickness, the first hard mask layer has a third thickness, and the photoresist layer has a fourth thickness.

In some embodiments, a thickness of the second hard mask layer is less than the third thickness of the first hard mask layer with a thickness difference after forming the plurality of trenches.

In some embodiments, the thickness difference is 10 nm.

In some embodiments, the substrate includes a plurality of active areas and a contacting layer. The active areas are formed in an upper portion of the substrate in the array area. The contacting layer is formed on the active areas in the array area and the peripheral area, and the contacting layer includes a plurality of contact plugs.

In some embodiments, the plurality of trenches expose a surface of the contacting layer, and positions of the plurality of trenches is corresponding to the plurality of contact plugs, respectively.

In some embodiments, forming the capacitor in each of the plurality of trenches includes the following steps. A first conductive layer is deposited on an inner surface of each of the trenches. The first conductive layer directly contacts each of the contact plugs. An insulating layer is deposited on the first conductive layer. A second conductive layer is deposited on the insulating layer.

Embodiments of this disclosure provide a method of manufacturing a capacitor array, including the following steps. A substrate including a first cap layer over the substrate, a second cap layer on the first cap layer and a first hard mask layer on the second cap layer is provided. The substrate is defined with an array area and a peripheral area. A photoresist layer is formed on the first hard mask layer in the array area and the first hard mask layer in the peripheral area is exposed. A N-type impurity is doped in the first hard mask layer exposed by the photoresist layer to form a second hard mask layer in the peripheral area. A pattern layer on the first hard mask layer and the second hard mask layer is formed to expose a plurality of exposing portions on a surface of the second hard mask layer. The second hard mask layer, the second cap layer and the first cap layer at the plurality of exposing portions are etched to form a plurality of trenches. Aa capacitor is formed in each of the plurality of trenches

In some embodiments, a concentration of the N-type impurity is a range from 2×10¹⁴ to 2×10¹⁸ ions/cm².

In some embodiments, the N-type impurity is arsenic.

In some embodiments, forming the plurality of trenches is performed by a dry etching process with halogen-based gas.

In some embodiments, the first cad layer has a first thickness, the second cad layer has a second thickness, the first hard mask layer has a third thickness, and the photoresist layer has a fourth thickness.

In some embodiments, a thickness of the second hard mask layer is less than the third thickness of the first hard mask layer with a thickness difference after forming the plurality of trenches.

In some embodiments, the thickness difference is 10 nm.

In some embodiments, the substrate includes a plurality of active areas and contacting layer. The active areas are formed in an upper portion of the substrate in the array area. The contacting layer is formed on the active areas in the array area and the peripheral area, and the contacting layer includes a plurality of contact plugs.

In some embodiments, the plurality of trenches expose a surface of the contacting layer, and positions of the plurality of trenches is corresponding to the plurality of contact plugs, respectively.

In some embodiments, forming the capacitor in each of the plurality of trenches includes the following steps. A first conductive layer is deposited on an inner surface of each of the trenches. The first conductive layer directly contacts each of the contact plugs. An insulating layer is deposited on the first conductive layer. A second conductive layer is deposited on the insulating layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1 to 6 are cross-sectional views of different stages of a method of manufacturing a capacitor array of a semiconductor structure according a first embodiment of the present disclosure; and

FIGS. 7 to 9 are cross-sectional views of different stages of a method of manufacturing a capacitor array of a semiconductor structure according a second embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

In related art, after a storage structure is etched by height aspect ratio contact (HARC), a hard mask layer (such as a polysilicon mask) in an array area and the hard mask layer in a peripheral area have a great height difference, such as 350 nm. Thus, a cap layer, such as a nitride layer, in the array area and the cap layer in the peripheral area has an etched difference, such as 20 nm after a subsequent etch back process for forming trenches for capacitors due to the lower height in the array area, causing a high-step structure. Further, a bowed critical dimension (CD) of each of the trenches is stretched. As a result, source leakage of a storage element (SSLK) is caused due the loss cap layer and the stretched CD. In order to solve the problems mentioned above, embodiments of this disclosure provide a method of manufacturing a capacitor array of a semiconductor structure through implanting an impurity in a hard mask layer before forming trenches for capacitors.

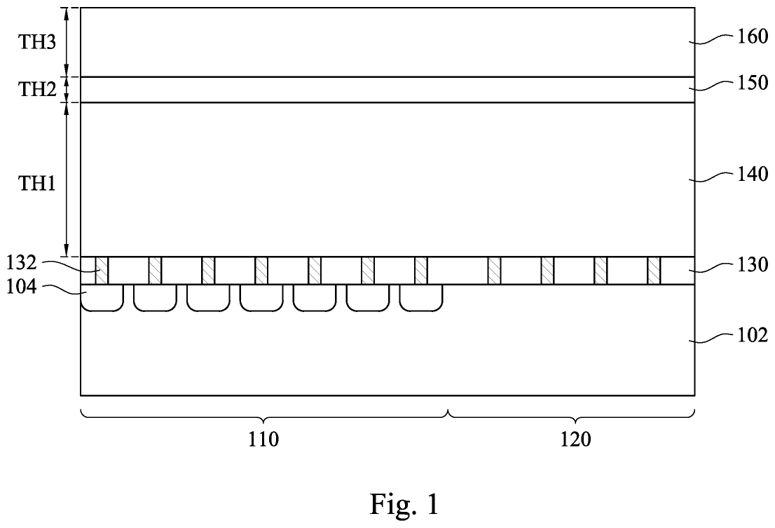

Please refer to FIGS. 1-6. FIGS. 1-6 are cross-sectional views of a method of manufacturing a capacitor array of a semiconductor structure at various process stages according to a first embodiment of this disclosure.

Firstly, in FIG. 1, a substrate 102 is provided and defined with an array area 110 and a peripheral area 120. The substrate 102 includes a plurality of active areas 104 with a plurality of source/drain (S/D) regions (not shown) in the array area 110 and a contacting layer 130 with a plurality of contact plugs 132 in array area 110 and the peripheral area 120. In addition, the contact plugs 132 in the array area 110 are formed over the active areas 104.

In some embodiments, the substrate 102 may include silicon, such as crystalline silicon, polycrystalline silicon, or amorphous silicon. The substrate 102 may include an elemental semiconductor, such as germanium. In some embodiments, the substrate 102 may include alloy semiconductors, such as silicon germanium, silicon germanium carbide, gallium indium phosphide, or other suitable materials. In some embodiments, the substrate 102 may include compound semiconductors, such as silicon carbide (SiC), gallium arsenide (GaAs), indium phosphide (InP), indium arsenide (InAs), or other suitable materials. Moreover, in some embodiments, the 102 substrate can optionally have a semiconductor-on-insulator (SOI) structure.

Further, in FIG. 1, a first cap layer 140 is deposited on the contacting layer 130 to a first thickness TH1. In some embodiments, the first cap layer 140 includes oxide. In some embodiments, the first thickness TH1 of the first cap layer 140 is 1.8 μM. Subsequently, a second cap layer 150 is deposited on the first cap layer 140 to a second thickness TH2. In some embodiments, the second cap layer 150 includes nitride. In some embodiments, the second thickness TH2 of the second cap layer 150 is 0.1 μM. Then, a hard mask layer 160 is formed on the second cap layer 150 to a third thickness TH3. In some embodiments, the hard mask layer 160 includes polysilicon. In some embodiments, the third thickness TH3 of the hard mask layer 160 is 0.5 to 0.6 μM.

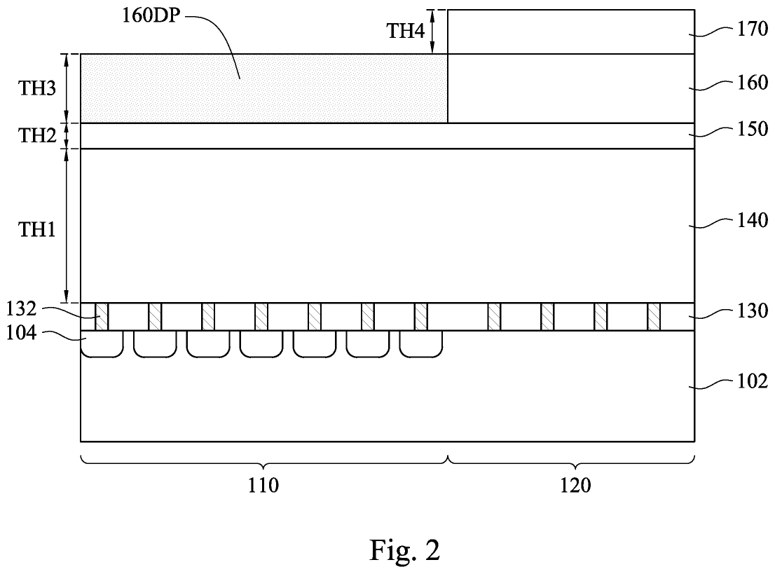

Next, in FIG. 2, a photoresist layer 170 is formed on the hard mask layer 160 in the peripheral area 120 to expose an exposed portion of the hard mask layer 160 in the array area 110. In some embodiments, the photoresist layer 280 has a fourth thickness TH4. In some embodiments, the fourth thickness TH4 is 0.2 μM. Subsequently, the exposed potion of the hard mask layer 160 is doped with a P-type impurity to form a doped hard mask layer 160DP. In addition, a doping depth of the P-type impurity is identical to the third thickness TH3 of the hard mask layer 160. In some embodiments, a concentration of the P-type impurity is a range from 2×10¹⁴ to 2×10¹⁸ ions/cm². In some embodiments, the P-type impurity is Boron. In addition, the photoresist layer 170 is removed through stripping after doping the P-type impurity.

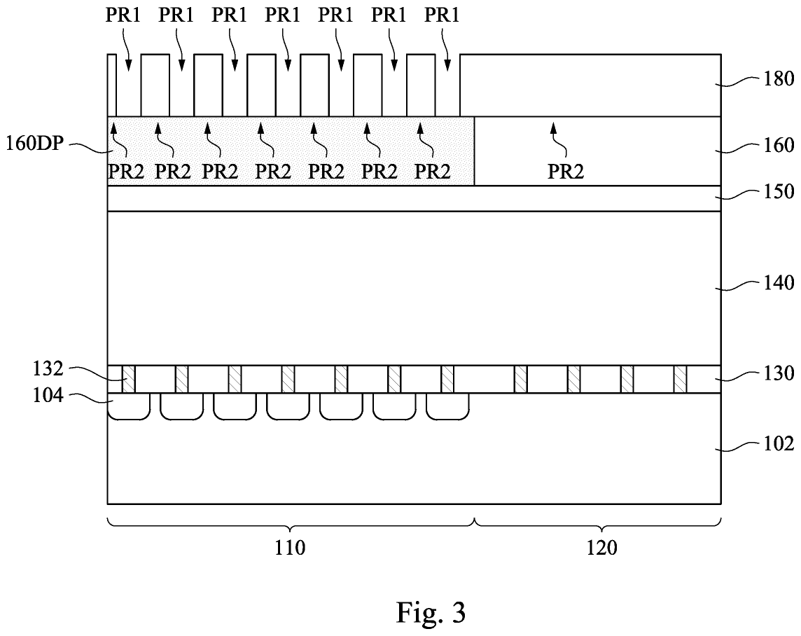

Further, in FIG. 3, a pattern layer 180 is formed on the hard mask layer 160 and the doped hard mask layer 160DP. The pattern layer 180 exposes a plurality of first portions PR1 of a surface of the doped hard mask layer 160DP and covers a plurality of second portions PR2 of the surface of the doped hard mask layer 160DP and a surface of the hard mask layer 160. After forming the pattern layer 180, a photolithography process is performed on the hard mask layer 160 and the doped hard mask layer 160DP. Specifically, the photolithography process is performed on the pattern layer 180 and the first portions PR1 of the exposed surface of the doped hard mask layer 160DP.

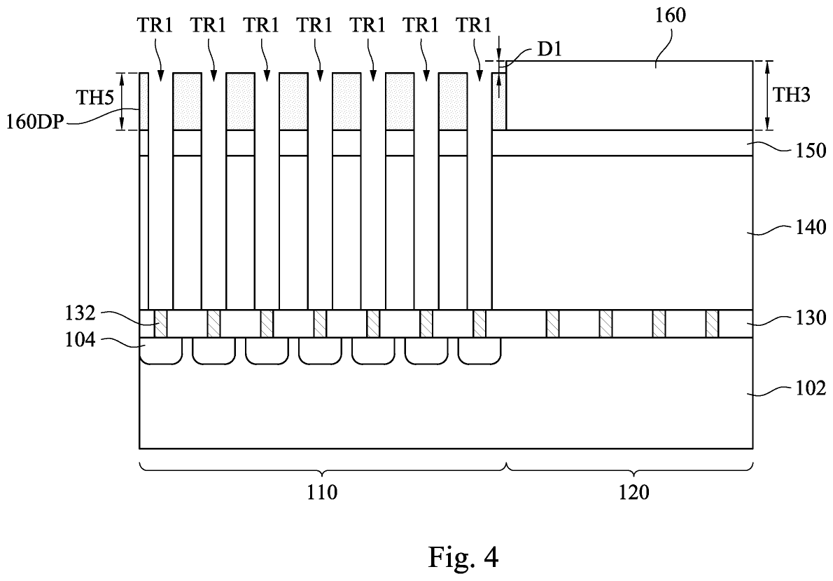

Subsequently, in FIG. 4, a plurality of first trenches TR1 are formed in the doped hard mask layer 160DP, the second cap layer 150 and the first cap layer 140 at the first portions (such as the first portions PR1 in FIG. 3) until exposing a surface of the contacting layer 130 through an etching process. Moreover, the pattern layer (such as the pattern layer 180 in FIG. 3) is removed after forming the first trenches TR1. In addition, a thickness of the doped hard mask layer 160DP becomes a fifth thickness TH5 after the etching process. In some embodiments, a thickness difference D1 of the third thickness TH3 and the fifth thickness TH5 is 10 nm. In some embodiments, positions of the first trenches TR1 are corresponding to the contact plugs 132 in the array area 110, respectively. In some embodiments, the etching process is a dry etching process by gas. In some embodiments, the gas is a halogen-based gas. In some embodiments, the halogen-based gas is Cl_{2(g)}.

Additionally, the P-type impurity in doped hard mask layer 160DP in array area 110 increases an etching resistance of the doped hard mask layer 160DP to the gas, such as halogen-based gas. Specifically, a non-volatile by product, oxychloride of the P-impurity, such as BOClₓ, is generated during the dry etching process, which reduces an etching rate. In this way, source leakage of a storage element (SSLK) caused by the high-step structure can be reduced and a uniformity of the hard mask layer 160 and the doped hard mask layer 160DP can be improved through the embodiments of this disclosure.

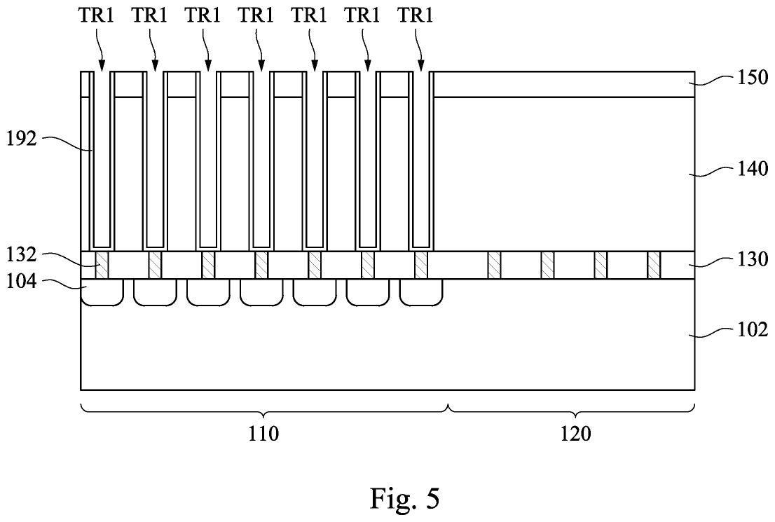

Further, in FIG. 5, a first conductive layer 192 is formed in an inner surface of each of the first trenches TR1 by depositing after the doped hard mask layer (such as the doped hard mask layer 160DP in FIG. 4) and the hard mask layer (such as the hard mask layer 160 in FIG. 4) are removed. Also, the first conductive layer 192 contacts the surface of the contacting layer 130 exposed by each of the first trenches TR1, and more specifically, the first conductive layer 192 contacts the contact plugs 132 in the array area 110, respectively. In some embodiments, a material of the first conductive layer 192 includes metal and polysilicon. In some embodiments, the first conductive layer 192 is formed through a chemical vapor deposition (CVD) process, a physical vapor deposition (PVD) process, an atomic layer deposition (ALD) process or any suitable deposition process.

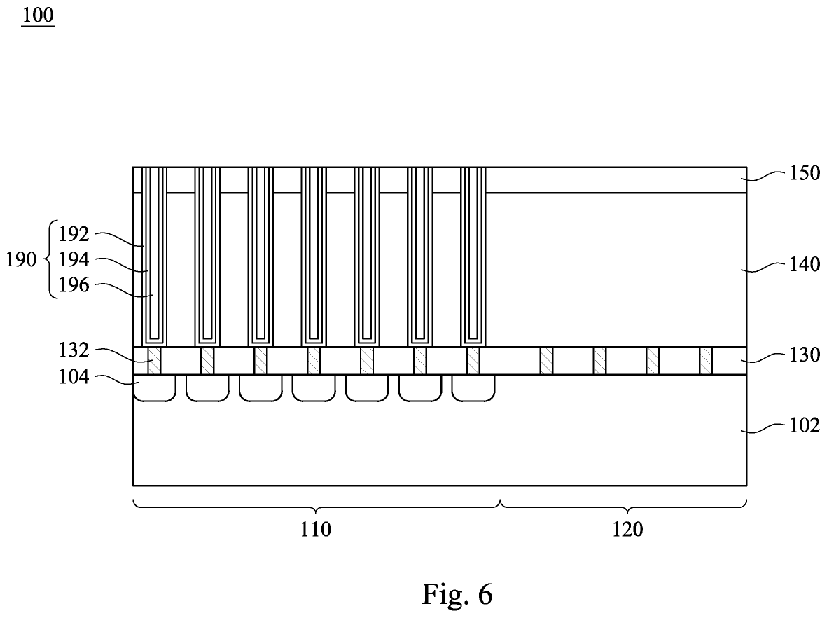

Next, in FIG. 6, an insulating layer 194 is formed on the first conductive layer 192 and a second conductive layer 196 is formed on the insulating layer 194. In some embodiments, the insulating layer 194 and the second conductive layer 196 are deposited through such as CVD process, PVD process, ALD process or any suitable deposition process. In some embodiments, the insulating layer 194 includes oxide. In some embodiments, the second conductive layer 196 includes metal and polysilicon. It is worth to mention that a capacitor 190 including the first conductive layer 192, the insulating layer 194 and the second conductive layer 196 is formed in each of the trenches (such as trenches TR1 in FIG. 4). As well, the multiple capacitors 190 in the array area are formed a capacitor array of a semiconductor structure 100.

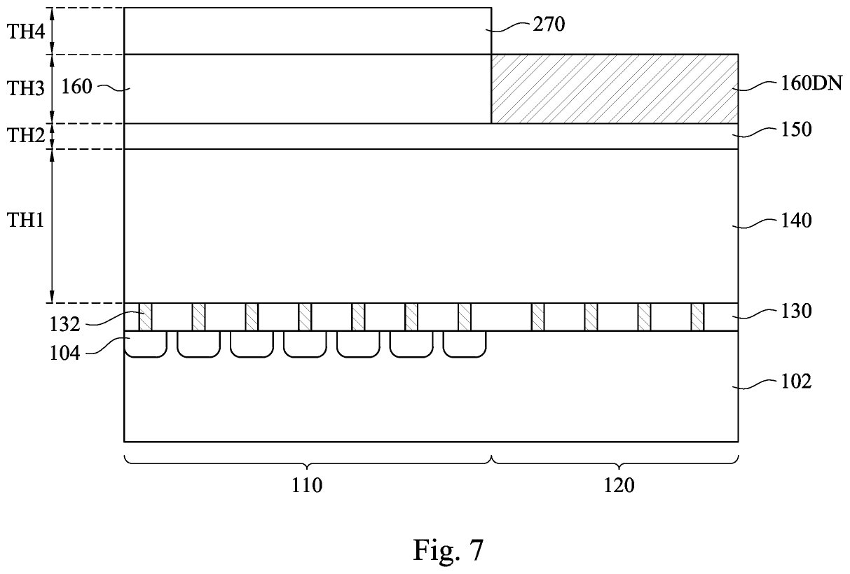

Further, the embodiments of this disclosure also provide another method of manufacturing a capacitor of a semiconductor structure. Please refer to FIGS. 7-9. FIGS. 7-9 are views of another method of manufacturing a capacitor of a semiconductor structure at various process stages according to a second embodiment of this disclosure.

The main difference between the first embodiment and the second embodiment is that an N-type impurity is doped in a hard mask layer in the peripheral area in the second embodiment. The details are described as follow.

In FIG. 7, the substrate 102 with the active areas 104 and the contacting layer 130 with the contact plugs 132 is provided. Also, the first cap layer 140, the second cap layer 150 and the hard mask layer 160 are formed on the contacting layer 130 in sequence. Moreover, the technical features of the substrate 102, the active areas 104, the contacting layer 130, the contact plugs 132, the first cap layer 140, the second cap layer 150 and the hard mask layer 160 are described above, and here will not repeated.

Further, a photoresist layer 270 is formed on the hard mask layer 160 in the array area 110 to expose an exposed portion of the hard mask layer 160 in the peripheral area 120. Next, the exposed portion of the hard mask layer is doped with the N-type impurity to form a doped hard mask layer 160DN. In addition, a doping depth of the N-type impurity is identical to the third thickness TH3 of the hard mask layer 160. In some embodiments, a concentration of the N-type impurity is a range from 2×10¹⁴ to 2×10¹⁸ ions/cm². In some embodiments, the N-type impurity is arsenic. In addition, the photoresist layer 270 is removed through stripping after doping the N-type impurity.

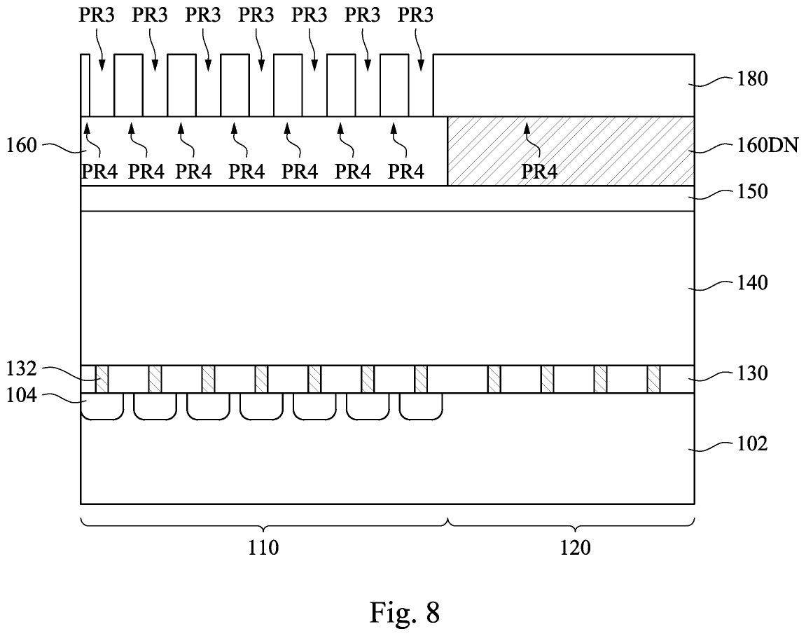

Next, in FIG. 8, a pattern layer 180 is formed on the hard mask layer 160 and the doped hard mask layer 160DN to expose a plurality of third portions PR3 of a surface of the hard mask layer 160 and cover a plurality of fourth portions PR4 of the surface of the hard mask layer 160 and a surface of the doped hard mask layer 160DN. Then, a photolithography process is performed on the pattern layer 180 and the third portions PR3 of the exposed surface of the hard mask layer 160.

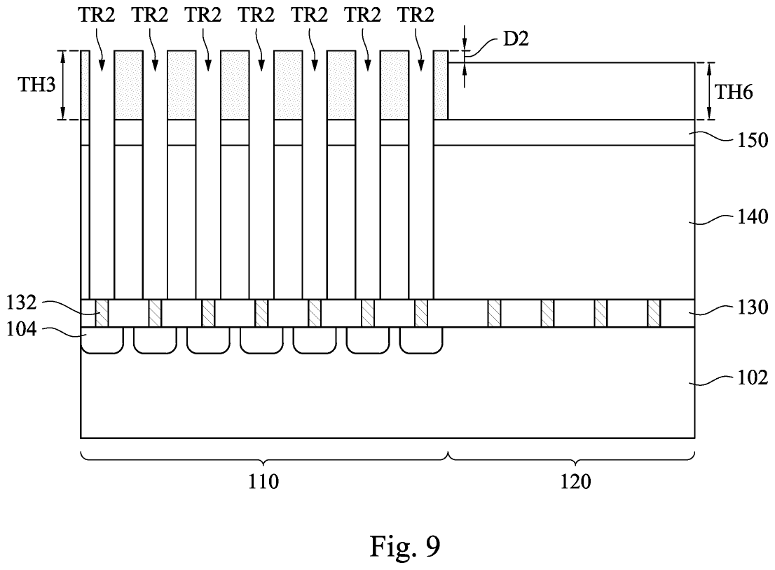

Further, in FIG. 9, the hard mask layer 160, the second cap layer 150 and the first cap layer 140 at the third portions (such as the third portions PR3 in FIG. 8) are etched until exposing the surface of the contacting layer 130 by an etching process to form a plurality of second trenches TR2. Moreover, the pattern layer (such as in FIG. 8) is removed after forming the second trenches TR2. In addition, a thickness of the doped hard mask layer becomes a sixth thickness TH6 after the etching process. In some embodiments, a thickness difference D2 of the third thickness TH3 and sixth thickness TH6 is 10 nm. In some embodiments, the etching process is a dry etching process by gas. In some embodiments, the gas is a halogen-based gas. In some embodiments, the halogen-based gas is Cl_{2(g)}.

Additionally, the N-type impurity, such as arsenic, in the doped hard mask layer 160DN in the peripheral area 120 increases an etching rate of the doped hard mask layer 160DN to the gas, such as halogen-based gas. The N-type impurity doped simply in the doped hard mask layer 160DN in the peripheral area 120 can increase the etching rate for the he doped hard mask layer 160DN in the peripheral area 120, which can reduce the high-step structure. In this way, the uniformity of the hard mask layer 160 and the doped hard mask layer 160DN can be improved, and further source leakage of a storage element (SSLK) caused by the high-step structure can be reduced.

Furthermore, in the second embodiment, after forming the second trenches TR2, the hard mask layer 160 and the doped hard mask layer 160DN are removed. Subsequently, a first conductive layer is formed on an inner surface of each of the second trenches TR2. As well, an insulating layer is formed on the first conductive layer and a second conductive layer is formed on the insulating layer, so as to form a capacitor in each of the second trenches TR2, of which structure is similar to a structure shown in FIG. 5. Therefore, the similar descriptions are not repeated here.

As stated as above, in the embodiments of doping P-type impurity, the source leakage of a storage element (SSLK) caused by the high-step structure can be reduce through increasing the ability of etching resistance of a hard mask in an array area. In addition, in the embodiments of doping N-type impurity, the source leakage of a storage element (SSLK) caused by the high-step structure can be reduce through increasing an etching rate of a hard mask in a peripheral area.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a capacitor array, comprising:
providing a substrate including a first cap layer over the substrate, a second cap layer on the first cap layer and a first hard mask layer on the second cap layer, wherein the substrate is defined with an array area and a peripheral area;
forming a photoresist layer on the first hard mask layer in the peripheral area and exposing the first hard mask layer in the array area;
doping a P-type impurity in the first hard mask layer exposed by the photoresist layer to form a second hard mask layer;
forming a pattern layer on the first hard mask layer and the second hard mask layer to expose a plurality of exposing portions on a surface of the second hard mask layer;
etching the second hard mask layer, the second cap layer and the first cap layer at the plurality of exposing portions to form a plurality of trenches; and
forming a capacitor in each of the plurality of trenches.

2. The method of claim 1, wherein a concentration of the P-type impurity is a range from 2×10¹⁴ to 2×10¹⁸ ions/cm².

3. The method of claim 1, wherein the P-type impurity is boron.

4. The method of claim 1, wherein forming the plurality of trenches is performed by a dry etching process with halogen-based gas.

5. The method of claim 1, wherein the first cap layer has a first thickness, the second cap layer has a second thickness, the first hard mask layer has a third thickness, and the photoresist layer has a fourth thickness.

6. The method of claim 5, wherein a thickness of the second hard mask layer is less than the third thickness of the first hard mask layer with a thickness difference after forming the plurality of trenches.

7. The method of claim 6, wherein the thickness difference is 10 nm.

8. The method of claim 1, wherein the substrate comprises:
a plurality of active areas, disposed in an upper portion of the substrate in the array area; and
a contacting layer, disposed on the plurality of active areas in the array area and the peripheral area, and comprising a plurality of contact plugs.

9. The method of claim 8, wherein the plurality of trenches expose a surface of the contacting layer, and positions of the plurality of trenches is corresponding to the plurality of contact plugs, respectively.

10. The method of claim 9, wherein forming the capacitor in each of the plurality of trenches comprises:
depositing a first conductive layer on an inner surface of each of the plurality of trenches, wherein the first conductive layer directly contacts each of the plurality of contact plugs;
depositing an insulating layer on the first conductive layer; and
depositing a second conductive layer on the insulating layer.

11. A method of manufacturing a capacitor array, comprising:
providing a substrate including a first cap layer over the substrate, a second cap layer on the first cap layer and a first hard mask layer on the second cap layer, wherein the substrate is defined with an array area and a peripheral area;
forming a photoresist layer on the first hard mask layer in the array area and exposing the first hard mask layer in the peripheral area;
doping a N-type impurity in the first hard mask layer exposed by the photoresist layer to form a second hard mask layer in the peripheral area;
forming a pattern layer on the first hard mask layer and the second hard mask layer to expose a plurality of exposing portions on a surface of the second hard mask layer;
etching the second hard mask layer, the second cap layer and the first cap layer at the plurality of exposing portions to form a plurality of trenches; and
forming a capacitor in each of the plurality of trenches.

12. The method of claim 11, wherein a concentration of the N-type impurity is a range from 2×10¹⁴ to 2×10¹⁸ ions/cm².

13. The method of claim 11, wherein the N-type impurity is arsenic.

14. The method of claim 11, wherein forming the plurality of trenches is performed by a dry etching process with halogen-based gas.

15. The method of claim 11, wherein the first cap layer has a first thickness, the second cap layer has a second thickness, the first hard mask layer has a third thickness, and the photoresist layer has a fourth thickness.

16. The method of claim 15, wherein a thickness of the second hard mask layer is less than the third thickness of the first hard mask layer with a thickness difference after forming the plurality of trenches.

17. The method of claim 16, wherein the thickness difference is 10 nm.

18. The method of claim 11, wherein the substrate comprises:
a plurality of active areas, disposed in an upper portion of the substrate in the array area; and
a contacting layer, disposed on the plurality of active areas in the array area and the peripheral area, and comprising a plurality of contact plugs.

19. The method of claim 18, wherein the plurality of trenches expose a surface of the contacting layer, and positions of the plurality of trenches is corresponding to the plurality of contact plugs, respectively.

20. The method of claim 19, wherein forming the capacitor in each of the plurality of trenches comprises:
depositing a first conductive layer on an inner surface of the plurality of trenches, wherein the first conductive layer directly contacts each of the plurality of contact plugs;
depositing an insulating layer on the first conductive layer; and
depositing a second conductive layer on the insulating layer.
